(19) United States
(12) Patent Application Publication
(10) Pub. No.: US 2010/0170557 A1
(43) Pub. Date: Jul. 8, 2010

(54) High Efficiency Solar Cell With Surrounding Silicon Scavenger Cells

(76) Inventors: Allen M. Barnett, Landenberg, PA (US); Kevin Warren Allison, Goleta, CA (US); Keith W. Goosen, Howell, NJ (US); Michael W. Haney, Oak Hill, VA (US); Christiana Beatrice Honsberg, Tempe, AZ (US)

Correspondence Address: POTTER ANDERSON & CORROON LLP;ATTN: JANET E. REED, PH.D., P.O. BOX 951, WILMINGTON, DE, 19899-0951, US

(21) Appl. No.: 12/358,878

(22) Filed: Jan. 23, 2009

Related U.S. Application Data
(63) Continuation of application No. PCT/US2007/016695, filed on Jul. 25, 2007.
(60) Provisional application No. 60/857,635, filed on Nov. 8, 2006.
(60) Provisional application No. 60/834,035, filed on Jul. 28, 2006.

(51) Int. Cl. H01L 31/042

(52) U.S. Cl. 136/244

(57) ABSTRACT

This invention relates to an improved high efficiency solar cell. The improvement comprises the addition of one or more silicon cells to surround at least a portion of the active region of the solar cell. Preferably, the silicon cells completely surround the active region of the solar cell. The silicon cells act as scavenger cells to absorb light that would otherwise not be absorbed by other components of the solar cell and to convert that energy to electricity.

### CROSS-REFERENCE TO RELATED APPLICATION

This Application is a Continuation of International Application Number PCT/US2007/016695, filed Jul. 25, 2007, which claims priority to U.S. Provisional Application. No. 60/834,035, filed on Jul. 28, 2006, and U.S. Provisional Application No. 60/857,635, filed Nov. 8, 2006, each of which is incorporated by reference herein in their entireties.

This invention was made with Government support under Agreement W911 NF-05-9-0005 awarded by the Government. The Government has certain rights in the invention.

The invention claimed herein was made pursuant to the Articles of Collaboration for the 50% Efficient Solar Cells Consortium formed pursuant to the Defense Advanced Research Projects Agency (DARPA) award to the University of Delaware Oct. 1, 2005, W911 NF-05-9-0005.

### FIELD OF THE INVENTION

This invention relates to an improved high efficiency solar cell with one or more surrounding silicon scavenger cells. This solar cell is suitable for use in both mobile and stationary applications.

### BACKGROUND OF THE INVENTION

Solar cell development has been in progress for over fifty years. One-junction silicon solar cells have received much attention over that period and are used in terrestrial photovoltaic applications. However, a one-junction silicon solar cell captures less than half of the theoretical potential for solar energy conversion with the best laboratory solar cells currently providing only about 24.7% efficiency. This limits the application of such cells.

High performance photovoltaic systems are required for both economic and technical reasons. The cost of electricity can be halved by doubling the efficiency of the solar cell. Many applications do not have the area required to provide the needed power using current solar cells.

Two types of solar cell architecture have been proposed for more efficient solar cells. One is a lateral architecture. An optical dispersion element is used to split the solar spectrum into its wavelength components. Separate solar cells are placed under each wavelength band and the cells are chosen so that they provide good efficiency for light of that wavelength band. Another architecture is a vertical one in which individual solar cells with different energy gaps are arranged in a stack. These are commonly referred to as cascade, tandem or multiple junction cells The solar light is passed through the stack.

There is a need for the development of high efficiency solar cells.

### SUMMARY OF THE INVENTION

This invention provides an improved high efficiency solar cell, the improvement comprising one or more silicon cells surrounding at least a portion of the active region of the solar cell.

In one preferred embodiment, silicon cells completely surround the active region of the solar cell.

Preferred, in one aspect of the invention, is an improved high efficiency solar cell with an architecture selected from the group consisting of a “high energy gap cell (HEGC) stack-dichroic mirror” architecture, a “HEGC stack-dichroic mirror-mid energy gap cell (MEGC) stack” architecture, a “HEGC stack-dichroic mirror-low energy gap cell (LEGC) stack” architecture and a “HEGC stack-dichroic mirror-MEGC stack-LEGC stack” architecture.

Preferred, in another aspect of the invention, is an improved high efficiency solar cell comprising:
a) a solar module comprising a III-V cell and a silicon cell with an area larger than that of the III-V cell; and
b) means to focus light from the sun's disc onto the III-V cell, wherein the silicon cell is positioned adjacent to the side of the III-V cell opposite the side upon which the light from the sun's disc impinges.

### BRIEF DESCRIPTION OF THE FIGURES

FIG. 1 shows a schematic drawing of a cell stack.

FIG. 2 illustrates an embodiment of the improved solar cell with a “HEGC stack-dichroic mirror” architecture with a dichroic mirror that reflects light with photons of energy≧E_{g}^{m} and transmits light with photons of energy<E_{g}^{m} and silicon cells completely enclosing the active region of the solar cell.

FIG. 3 illustrates an embodiment of the improved solar cell with a “HEGC stack-dichroic mirror-MEGC stack” architecture with a dichroic mirror that reflects light with photons of energy≧E_{g}^{m} and transmits light with photons of energy<E_{g}^{m} and silicon cells completely enclosing the active region of the solar cell.

FIG. 4 illustrates an embodiment of the improved solar cell with a “HEGC stack-dichroic mirror-LEGC stack” architecture with a dichroic mirror that reflects light with photons of energy≧E_{g}^{m} and transmits light with photons of energy≧E_{g}^{m} and silicon cells completely enclosing the active region of the solar cell.

FIG. 5 illustrates an embodiment of the improved solar cell with a “HEGC stack-dichroic mirror-MEGC stack-LEGC stack” architecture with a dichroic mirror that reflects light with photons of energy≧E_{g}^{m} and transmits light with photons of energy<E_{g}^{m} and silicon cells completely enclosing the active region of the solar cell.

FIG. 6 illustrates an embodiment of the improved solar cell comprising a solar module and means to focus light from the sun's disc onto the III-V cell.

FIG. 7 illustrates an embodiment of the improved solar cell with a “HEGC stack-dichroic mirror-MEGC stack-LEGC stack” architecture with a dichroic mirror that reflects light with photons of energy≧E_{g}^{m} and transmits light with photons of energy<E_{g}^{m} and silicon cells that enclose a portion of the active region of the solar cell.

### DETAILED DESCRIPTION OF THE PREFERRED EMBODIMENTS

The instant invention provides an improved high efficiency solar cell. The improved high efficiency solar cell has an efficiency in excess of 30% and, preferably, up to and surpassing 50%. The improvement is the addition of one or more silicon cells to act as scavenger cells to absorb light that would otherwise not be absorbed and to convert that energy to electricity. The silicon cells surround at least a portion of the active region of the solar cell and, preferably, completely surround the active region of the solar cell. The silicon cells provided by this invention increase the efficiency of the solar cell.

Preferably, in one aspect of the invention, the improved high efficiency solar cell has a “HEGC stack-dichroic mirror” architecture, a “HEGC stack-dichroic mirror-MEGC stack” architecture, a “HEGC stack-dichroic mirror-LEGC stack” architecture or a “HEGC stack-dichroic mirror-MEGC stack-LEGC stack” architecture. Especially preferred is the “HEGC stack-dichroic mirror-MEGC stack-LEGC stack” architecture.

In one embodiment of a solar cell with the “HEGC stack-dichroic mirror” architecture, the solar cell is comprised of a high energy gap cell and a dichroic mirror to split the light transmitted by the high energy gap cell. In this solar cell architecture, the exposure of a high energy gap cell to the solar light before there is any splitting of the solar light into spectral components by a dispersion device plays a key role in enabling the achievement of a high efficiency solar cell and in providing various embodiments of the solar cell. This architecture provides efficient use of all portions of the solar spectrum in a manner that enables a practical high efficiency solar cell. The high energy cell absorbs the higher energy photons of energy≧E_{g}^{h}, i.e., the blue-green to ultraviolet portion of the solar light, and converts that energy into electricity. The high energy cell is transparent to and transmits the photons of energy<E_{g}^{h}. Spectral splitting of the remaining light, i.e., the light transmitted by the high energy gap cell is then performed by means of the dichroic mirror. Since the blue-green to ultraviolet light has been absorbed by the high energy gap cell before the spectral splitting, requirements for the dichroic mirror are relaxed. Therefore improved and less costly splitting of the remaining light can be achieved. Requirements on the cells used to absorb the remaining light and convert that energy into electricity are also relaxed. As a result a practical, high efficiency solar cell can be achieved.

The dichroic mirror operating at E_{g}^{m} is positioned so that the light transmitted by the high energy gap cell impinges upon the dichroic mirror. The so-called “cold” dichroic mirror reflects light with photons of energy≧E_{g}^{m} and transmits light with photons of energy<E_{g}^{m}. The so-called “hot” dichroic mirror transmits light with photons of energy≧E_{g}^{m} and reflects light with photons of energy<E_{g}^{m}. The light reflected by and transmitted by the dichroic mirror can then be absorbed by other cells and the energy converted into electricity.

In another embodiment of a solar cell with the “HEGC stack-dichroic mirror” architecture, the high energy gap cell upon which the solar light impinges is one of two or more high energy gap cells with different energy gaps all of which ≧E_{g}^{h}. The cells are arranged vertically in a stack in descending order of their energy gaps with the first cell having the largest energy gap. The first cell absorbs photons of energy greater than or equal to its energy gap and is transparent to and transmits photons of energy less than its energy gap. The second cell in the stack has a lower energy gap thar the first cell and absorbs photons of energy greater than or equal to its energy gap and is transparent to and transmits photons of energy less than its energy gap. Similarly with any other cells present in the stack. In this embodiment, the dichroic mirror operating at E_{g}^{m} is positioned so that the light transmitted by the HEGC stack impinges upon the dichroic mirror. Again, the light reflected by and transmitted by the dichroic mirror can then be absorbed by other cells and the energy converted into electricity. The description of a HEGC stack that contains one or more cells with different energy gaps arranged vertically in descending order of their energy gaps with the first cell having the largest energy gap of the one or more cells in the HEGC stack cells, wherein solar light impinges upon the surface of the first cell in the HEGC stack, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap encompasses both of the above described embodiments, that having only one high energy gap cell and that having more than one high energy gap cell. These solar cells are herein referred to as solar cells with the “HEGC stack-dichroic mirror” architecture. A solar cell with the “HEGC stack-dichroic mirror” architecture is a solar cell comprising:
(a) a high energy gap cell (HEGC) stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack; and
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy≧E_{g}^{m} and one component of light with photons of energy≧E_{g}^{m} and wherein one of these components is reflected by the dichroic mirror and one is transmitted by the dichroic mirror.

The solar cell with the “HEGC stack-dichroic mirror-MEGC” stack architecture is comprised of a mid energy gap cell MEGC stack in addition to the HEGC stack and the dichroic mirror The component of light with photons of energy≧E_{g}^{m} is arranged to impinge upon the MEGC stack. As used herein, a solar cell with the “HEGC stack-dichroic mirror-MEGC stack” architecture is a solar cell comprising:
(a) a high energy gap cell (HEGC) stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack;
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy≧E_{g}^{m} and one component of light with photons of energy<E_{g}^{m} and wherein one of these components is reflected by the dichroic mirror and one is transmitted by the dichroic mirror; and
(c) a MEGC stack that contains one or more cells with different energy gaps arranged vertically in descending order of their energy gaps with the first cell having the largest energy gap of the one or more cells in the MEGC stack, the MEGC stack being positioned so that the component of light with photons of energy≧E_{g}^{m} impinges upon the surface of the first cell in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap.

The solar cell with the “HEGC stack-dichroic mirror-LEGC” stack architecture is comprised of a low energy gap cell LEGC stack in addition to the HEGC stack and the dichroic mirror. The component of light with photons of energy<E_{g}^{m} is arranged to impinge upon the LEGC stack. As used herein, a solar cell with the “HEGC stack-dichroic mirror-LEGC stack” architecture is a solar cell comprising:
(a) a high energy gap cell (HEGC) stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack;
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy≧E_{g}^{m} and one component of light with photons of energy<E_{g}^{m} and wherein one of these components is reflected by the dichroic mirror and one is transmitted by the dichroic mirror; and
(c) a LEGC stack that contains one or more cells with different energy gaps arranged vertically in descending order of their energy gaps with the first cell having the largest energy gap of the one or more cells in the LEGC stack, the LEGC stack being positioned so that the component of light with photons of energy<E_{g}^{m} impinges upon the surface of the first cell in the LEGC stack, wherein the energy gap of each cell in the LEGC stack is <E_{g}^{m} and wherein the one or more cells in the LEGC stack each absorb light with photons of energy greater than or equal to their energy gap and are transparent to and transmit light with photons of energy less than their energy gap.

The solar cell with the “HEGC stack-dichroic mirror-MEGC stack-LEGC stack” architecture is comprised of a MEGC stack and a LEGC stack in addition to the HEGC stack and the dichroic mirror. The component of light with photons of energy≧E_{g}^{m} is arranged to impinge upon the MEGC stack and the component of light with photons of energy<E_{g}^{m} is arranged to impinge upon the LEGC stack. As used herein, a solar cell with the “HEGC stack-dichroic mirror-MEGC stack-LEGC stack” architecture is a solar cell comprising:
(a) a high energy gap cell (HEGC) stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack;
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy≧E_{g}^{m} and one component of light with photons of energy<E_{g}^{m} and wherein one of these components is reflected by the dichroic mirror and one is transmitted by the dichroic mirror;
(c) a MEGC stack that contains one or more cells with different energy gaps arranged vertically in descending order of their energy gaps with the first cell having the largest energy gap of the one or more cells in the MEGC stack, the MEGC stack being positioned so that the component of light with photons of energy<E_{g}^{m} impinges upon the surface of the first cell in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap; and
(d) a LEGC stack that contains one or more cells with different energy gaps arranged vertically in descending order of their energy gaps with the first cell having the largest energy gap of the one or more cells in the LEGC stack, the LEGC stack being positioned so that the component of light with photons of energy<E_{g}^{m} impinges upon the surface of the first cell in the LEGC stack, wherein the energy gap of each cell in the LEGC stack is <E_{g}^{m} and wherein the one or more cells in the LEGC stack each absorb light with photons of energy greater than or equal to their energy gap and are transparent to and transmit light with photons of energy less than their energy gap.

Preferably, E_{g}^{m} is about equal to the energy gap of the cell with the lowest energy gap of all the cells to which the component of light with photons of energy≧E_{g}^{m} is directed.

“Cell” is used herein to describe the individual cells that are contained in the various stacks of the solar cell and to describe the silicon cells. These cells are generally referred to as solar cells. The term “solar cell” is used herein to describe the complete device.

As used herein, the “active region of the solar cell” refers to the region of the solar cell containing cells to absorb the incident light and any optical component used to split the spectrum of the light incident to it or direct light. When the solar cell has the “HEGC stack-dichroic mirror” architecture, the active region is the region containing the HEGC stack and the dichroic mirror. When the solar cell has the “HEGC stack-dichroic mirror-MEGC stack” architecture, the active region is the region containing the HEGC and MEGC stacks and the dichroic mirror. When the solar cell has the “HEGC stack-dichroic mirror-LEGC stack” architecture, the active region is the region containing the HEGC and LEGC stacks and the dichroic mirror. When the solar cell has the “HEGC stack-dichroic mirror-MEGC stack-LEGC stack” architecture, the active region is the region containing the HEGC, MEGC, and LEGC stacks and the dichroic mirror. Any other cells and reflecting mirrors present would also be included in the active region of the above architectures. When the solar cell contains the solar module, i.e., the group III-V/silicon dual cell, the active region comprises the III-V cell and any other cells and optical components present.

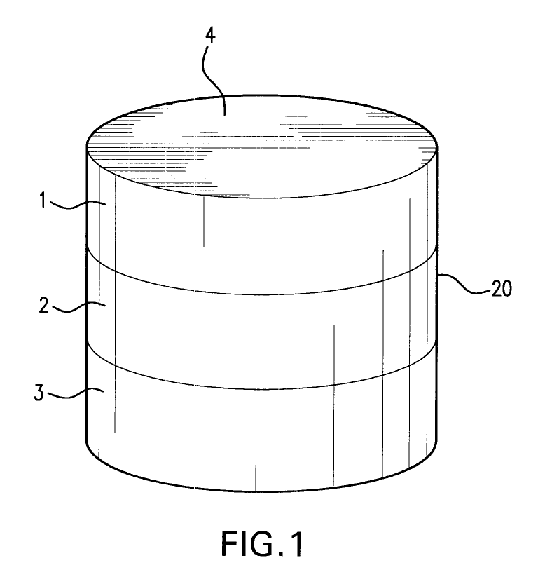

As indicated above, as used herein. “arranged vertically in descending order of their energy gaps with the first cell having the largest energy gap of the cells in the stack” means that the cells in the stack are arranged sequentially with the first cell having the largest energy gap, the second cell directly below the first cell having the next largest energy gap, the third cell directly below the second cell having the third largest energy gap, etc. This arrangement of a cell stack is shown schematically in FIG. 1. The cell stack 20 has three cells, 1, 2 and 3, with cell 1 being the first cell. The energy gaps of the three cells are such that E_{g}¹>E_{g}²>E_{g}³ where E_{g}¹ is the energy gap of cell 1, E_{g}² is the energy gap of cell 2 and E_{g}³ is the energy gap of cell 3. Cell 1 will absorb the light with photons of energy≧E_{g}¹ and transmit the light with photons of energy<E_{g}¹. Cell 2 will absorb the light with photons of energy≧E_{g}²and transmit the light with photons of energy<E_{g}². Similarly with cell 3. The cells convert the energy of the absorbed photons into electricity.

“Absorbed” as used herein means that a photon absorbed by the cell results in the creation of an electron-hole pair.

“The dichroic mirror operating at E_{g}^{m}” is used herein to mean that the dichroic mirror provides a separation of the light transmitted by the HEGC stack into two spectral components, one component of light with photons of energy≧E_{g}^{m} and one component of light with photons of energy<E_{g}^{m}. One of these components is reflected by the dichroic mirror and one is transmitted by the dichroic mirror. A “cold” dichroic mirror reflects light with photons of energy E_{g}^{m} and transmits light with photons of energy<E_{g}^{m} and a “hot” dichroic mirror transmits light with photons of energy≧E_{g}^{m} and reflects light with photons of energy<E_{g}^{m}. Typically the dichroic mirror will be positioned so that it is not perpendicular to the light transmitted by the HEGC stack. In this way the direction of the reflected light is not directly back toward the HEGC stack but is rather at an angle with respect to the direction of the light impinging on the dichroic mirror and the reflected light can more readily be arranged to impinge upon other cells. The transition from transmission to reflection occurs over a range of energies and corresponding wavelengths. The operating energy E_{g}^{m} is taken as the midpoint of this transition region. Unless the transition is extremely sharp, it is recognized that some photons of energy>E_{g}^{m} will be transmitted and some photons of energy<E_{g}^{m} will be reflected. In the transition range, the majority of photons with energies greater than E_{g}^{m} are reflected; the majority of photons with energies less than E_{g}^{m} are transmitted. The above definition of “the dichroic mirror operating at E_{g}^{m}” should be understood and interpreted in terms of this recognition of the nature of the transition region. For a given dichroic mirror, the operating energy shifts to lower energies (higher wavelengths) as the dichroic mirror is rotated away from being perpendicular to the direction of incidence of the light beam impinging upon it and “the dichroic mirror operating at E_{g}^{m}” should be understood and interpreted to apply to the position in which the dichroic mirror is placed relative to the direction of the impinging light. A dichroic mirror is a multilayer structure, typically containing 20 or more alternate layers of two transparent oxides. A sharper transition requires more layers and higher cost.

As used herein, “surrounding at least a portion of the active region of the solar cell” means that the one or more solar cells surround either completely or partially some of the components of the active region or that the one or more solar cells partially surround the whole active area.

The MEGC stack contains one or more cells with different energy gaps arranged vertically in descending order of their energy gaps with the first cell having the largest energy gap of the one or more cells in the MEGC stack. The MEGC stack is positioned so that the component of light with photons of energy≧E_{g}^{m} impinges upon the surface of the first cell in the MEGC stack. The energy gap of each cell in the MEGC stack is ≧E_{g}^{m} and <E_{g}^{h}. The one or more cells in the MEGC stack each absorb light with photons of energy greater than or equal to their energy gap and are transparent to and transmit light with photons of energy less than their energy gap. Preferably, the MEGC stack contains at least two cells.

The LEGC stack contains one or more cells with different energy gaps arranged vertically in descending order of their energy gaps with the first cell having the largest energy gap of the one or more cells in the LEGC stack. The LEGC stack is positioned so that component of light with photons of energy<E_{g}^{m} impinges upon the surface of the first cell in the LEGC stack. The energy gap of each cell in the LEGC stack is <E_{g}^{m}. The one or more cells in the LEGC stack each absorb light with photons of energy greater than or equal to their energy gap and are transparent to and transmit light with photons of energy less than their energy gap. Preferably, the LEGC stack contains at least two cells. Preferably, the energy gap of the cell with the lowest energy gap is sufficiently low to effective y absorb the majority of photons transmitted to it.

The light reflected and/or transmitted by the dichroic mirror can impinge directly upon the surface of the first cell in the appropriate stack. Alternatively, a reflecting mirror can be positioned so that light reflected and/or transmitted by the dichroic mirror is reflected by the reflecting mirror and directed to impinge upon the surface of the first cell in the appropriate stack, i.e., light with photons of energy≧E_{g}^{m} is directed to impinge upon the surface of the first cell in the MEGC stack and light with photons of energy<E_{g}^{m} is directed to impinge upon the surface of the first cell in the LEGC stack

The silicon cells of the invention are positioned to surround at least a portion of the active region of the solar cell and, preferably, all of the active region. When the silicon cells completely surround the active area, access must be provided to allow the solar light to enter that region. The purpose of these silicon scavenger cells is to intercept light not absorbed by the other cells and absorb and capture at least a portion of the energy contained in that light in order to increase the efficiency of the solar cell. When the silicon scavenger cells completely surround the active region they intercept all the stray light. Some of the stray light incident on the silicon scavenger cells is light that is not incident on the other cells present such as those of the MEGC and LEGC stacks, light reflected from these other cells, and light not absorbed by cells, for example, in the MEGC stack. While some of the diffuse light incident on the solar cell can be directed toward the MEGC and LEGC stacks, a portion can fail to impinge upon the MEGC and LEGC stacks. This portion can increase if the solar cell is not pointed directly at the sun. Thus the silicon cells of the invention contribute to the goal of higher efficiency and especially the goal of the solar cells with the preferred architecture for the efficient use of all portions of the solar spectrum. The silicon cells can be positioned along the interior walls of the solar cell container or positioned away from the interior walls and mounted on mounting boards. The silicon cells can be contiguous to other cells in the solar cell

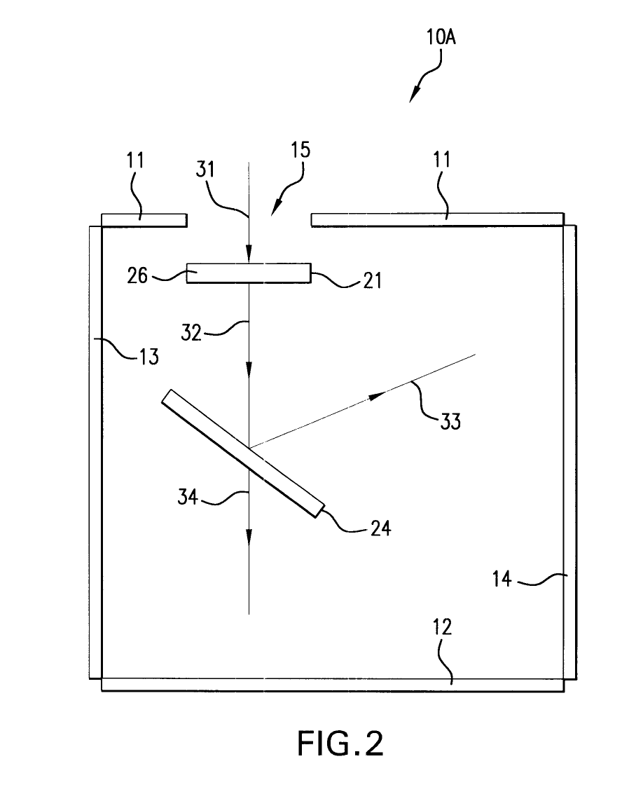

In FIGS. 2-5 and 7, the same numbers are used to identify the same entities. For, simplicity, the various light beams are represented by a light ray.

FIG. 2 illustrates an embodiment of the improved solar cell with the “HEGC stack-dichroic mirror” architecture and silicon scavenger cells completely surrounding the active region of the solar cell. The improved solar cell 10A is comprised of silicon cells 11-14, HEGC stack 21, and “cold” dichroic mirror 24. The silicon cells 11-14 along with two silicon cells not shown in the illustrative cross-section of the solar cell form a box-like confguration completely surrounding the active region. Silicon cell 11 forms the top of the box and the opening 15 provides access of the solar light to the active region. Silicon cell 12 forms the bottom of the box and cells 13 and 14 serve as the sides. A silicon cell, not shown, forms the front of the box in a plane above that of the cross-sectional plane of FIG. 2 and a second silicon cell, not shown, forms the back of the box in a plane below that of the cross-sectional plane of FIG. 2 to complete the box enclosure. The six cells in the box-like configuration completely surround the active region and intercept all stray light. The HEGC stack 21 as shown contains one cell 26 having an energy gap E_{g}^{h}. The dichroic mirror 24 operates at E_{g}^{m} and reflects light with photons of energy≧E_{g}^{m} and transmits light with photons of energy<E_{g}^{m}. Solar light 31 impinges upon the surface of the high energy gap cell 26. High energy gap cell 26 absorbs light with photons of energy≧E_{g}^{h} and transmits light 32 with photons of energy<E_{g}^{h}. The light 32 impinges upon the dichroic mirror 24 which is positioned so that it is not perpendicular to the direction of the light 32. Light 33 with photons of energy≧E_{g}^{m} is reflected by the dichroic mirror. Light 34 with photons of energy<E_{g}^{m} is transmitted by the dichroic mirror. Light 33 and light 34 would typically be arranged to impinge upon other cells.

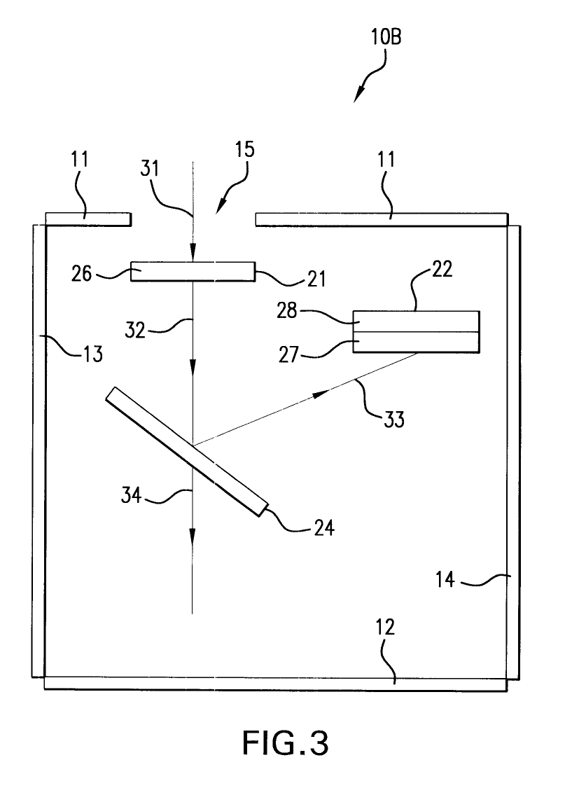

FIG. 3 illustrates an embodiment of the improved solar cell with the “HEGC stack-dichroic mirror-MEGC stack” architecture and silicon scavenger cells completely surrounding the active region of the solar cell. The improved solar cell 10B is comprised of silicon cells 11-14, HEGC stack 21, MEGC stack 22, and “cold” dichroic mirror 24. The silicon cells 11-14 along with two silicon cells not shown in the illustrative cross-section of the solar cell form a box-like configuration completely surrounding the active region. Silicon cell 11 forms the top of the box and the opening 15 provides access of the solar light to the active region. Silicon cell 12 forms the bottom of the box and cells 13 and 14 serve as the sides. A silicon cell, not shown, forms the front of the box in a plane above that of the cross-sectional plane of FIG. 3 and a second silicon cell, not shown, forms the back of the box in a plane below that of the cross-sectional plane of FIG. 3 to complete the box enclosure. The six cells in the box-like configuration completely surround the active region and intercept all stray light. The HEGC stack 21 as shown contains one cell 26 having an energy gap E_{g}^{h}. The MEGC stack 22 as shown contains two cells 27 and 28 with different energy gaps E_{g}²⁷ and E_{g}²⁸, where E_{g}²⁷ and E_{g}²⁸ are both ≧E_{g}^{m} and <E_{g}^{h} and E_{g}²⁷ is >E_{g}²⁸. The dichroic mirror 24 operates at E_{g}^{m} and reflects light with photons of energy≧E_{g}^{m} and transmits light with photons of energy<E_{g}^{m}. Solar light 31 impinges upon the surface of the high energy gap cell 26. High energy gap cell 26 absorbs light with photons of energy≧E_{g}^{h} and transmits light 32 with photons of energy<E_{g}^{h}. The light 32 impinges upon the dichroic mirror 24 which is positioned so that it is not perpendicular to the direction of the light 32. Light 33 with photons of energy≧E_{g}^{m} is reflected by the dichroic mirror and impinges upon the surface of the first cell 27 of the MEGC stack 22. Cells 27 and 28 each absorb light with photons of energy greater than or equal to their energy gap and are transparent to and transmit light with photons of energy less than their energy gap. Light 34 with photons of energy<E_{g}^{m} is transmitted by the dichroic mirror. Light 34 would typically be arranged to impinge upon other cells.

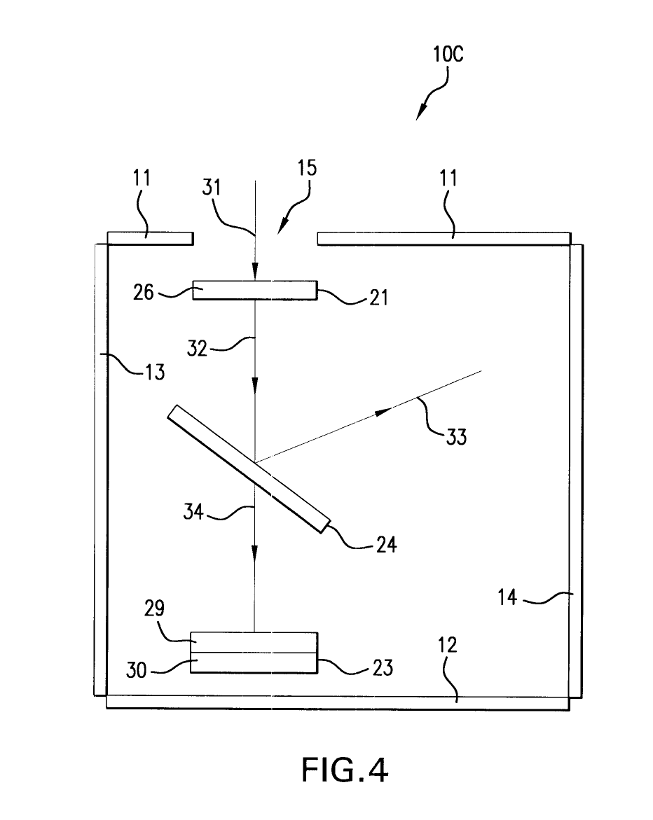

FIG. 4 illustrates an embodiment of the improved solar cell with the “HEGC stack-dichroic mirror-LEGC stack” architecture and silicon scavenger cells completely surrounding the active region of the solar cell. The improved solar cell 10C is comprised of silicon cells 11-14, HEGC stack 21, LEGC stack 23, and “cold” dichroic mirror 24. The silicon cells 11-14 along with two silicon cells not shown in the illustrative cross-section of the solar cell form a box-like configuration completely surrounding the active region. Silicon cell 11 forms the top of the box and the opening 15 provides access of the solar light to the active region. Silicon cell 12 forms the bottom of the box and cells 13 and 14 serve as the sides. A silicon cell, not shown, forms the front of the box in a plane above that of the cross-sectional plane of FIG. 4 and a second silicon cell, not shown, forms the back of the box in a plane below that of the cross-sectional plane of FIG. 4 to complete the box enclosure. The six cells in the box-like configuration completely surround the active region and intercept all stray light. The HEGC stack 21 as shown contains one cell 26 having an energy gap E_{g}^{h}. The LEGC stack 23 as shown contains two cells 29 and 30 with different energy gaps E_{g}²⁹ and E_{g}³⁰, where E_{g}²⁹ and E_{g}³⁰ are both <E_{g}^{m} and E_{g}²⁹ is >E_{g}³⁰. The dichroic mirror 24 operates at E_{g}^{m} and reflects light with photons of energy≧E_{g}^{m} and transmits light with photons of energy<E_{g}^{m}. Solar light 31 impinges upon the surface of the high energy gap cell 26. High energy gap cell 26 absorbs light with photons of energy≧E_{g}^{h} and transmits light 32 with photons of energy<E_{g}^{h}. The light 32 impinges upon the dichroic mirror 24 which is positioned so that it is not perpendicular to the direction of the light 32. Light 33 with photons of energy≧E_{g}^{m} is reflected by the dichroic mirror. Light 34 with photons of energy<E_{g}^{m} is transmitted by the dichroic mirror and impinges upon the surface of the first cell 29 of the LEGC stack 23. Cells 29 and 30 each absorb light with photons of energy greater than or equal to their energy gap and are transparent to and transmit light with photons of energy less than their energy gap. Light 33 would typically be arranged to impinge upon other cells

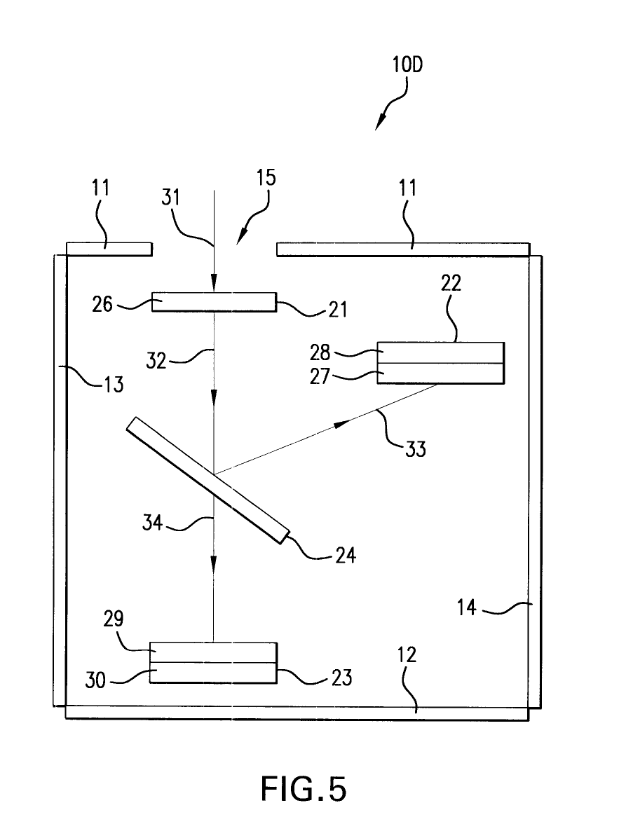

FIG. 5 illustrates an embodiment of the improved solar cell with the “HEGC stack-dichroic mirror-MEGC stack-LEGC stack” architecture and silicon scavenger cells completely surrounding the active region of the solar cell. The improved solar cell 10D is comprised of silicon cells 11-14, HEGC stack 21, MEGC stack 22, LEGC stack 23, and “cold” dichroic mirror 24. The silicon cells 11-14 along with two silicon cells not shown in the illustrative cross-section of the solar cell form a box-like configuration completely surrounding the active region. Silicon cell 11 forms the top of the box and the opening 15 provides access of the solar light to the active region. Silicon cell 12 forms the bottom of the box and cells 13 and 14 serve as the sides. A silicon cell, not shown, forms the front of the box in a plane above that of the cross-sectional plane of FIG. 5 and a second silicon cell, not shown, forms the back of the box in a plane below that of the cross-sectional plane of FIG. 5 to complete the box enclosure. The six cells in the box-like configuration completely surround the active region and intercept all stray light. The HEGC stack 21 as shown contains one cell 26 having an energy gap E_{g}^{h}. The MEGC stack 22 as shown contains two cells 27 and 28 with different energy gaps E_{g}ⁿand E_{g}²⁸, where E_{g}²⁷ and E_{g}²⁸ are both ≧E_{g}^{m} and <E_{g}^{h} and E_{g}²⁷ is >E_{g}²⁸. The LEGC stack 23 as shown contains two cells 29 and 30 with different energy gaps E_{g}²⁹ and E_{g}³⁰, where E_{g}²⁹ and E_{g}³⁰ are both <E_{g}^{m} and E_{g}²⁹ is >E_{g}³⁰. The dichroic mirror 24 operates at E_{g}^{m} and reflects light with photons of energy≧E_{g}^{m} and transmits light with photons of energy<E_{g}^{m}. Solar light 31 impinges upon the surface of the high energy gap cell 26. High energy gap cell 26 absorbs light with photons of energy≧E_{g}^{h} and transmits light 32 with photons of energy<E_{g}^{h}. The light 32 impinges upon the dichroic mirror 24 which is positioned so that it is not perpendicular to the direction of the light 32. Light 33 with photons of energy≧E_{g}^{m} is reflected by the dichroic mirror and impinges upon the surface of the first cell 27 of the MEGC stack 22. Cells 27 and 28 each absorb light with photons of energy greater than or equal to their energy gap and are transparent to and transmit light with photons of energy less than their energy gap. Light 34 with photons of energy<E_{g}^{m} is transmitted by the dichroic mirror and impinges upon the surface of the first cell 29 of the LEGC stack 23. Cells 29 and 30 each absorb light with photons of energy greater than or equal to their energy gap and are transparent to and transmit light with photons of energy less than their energy gap.

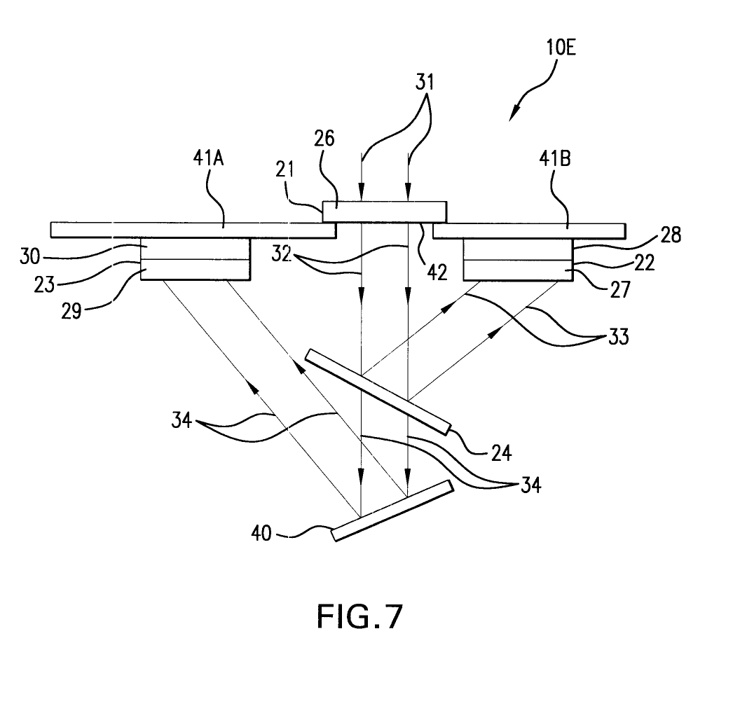

FIG. 7 illustrates embodiment of the solar cell with the “HEGC stack-dichroic mirror-MEGC stack-LEGC stack” architecture and silicon scavenger cells surrounding a portion of the active region of the solar cell. The solar cell 10E is comprised of HEGC stack 21, MEGC stack 22, LEGC stack 23, “cold” dichroic mirror 24, reflecting mirror 40 and two silicon scavenger cells 41A and 41B. The HEGC stack 21 as shown contains one cell 26 having an energy gap E_{g}^{h}. The MEGC stack 22 as shown contains two cells 27 and 28 with different energy gaps E_{g}²⁷ and E_{g}²⁸, where E_{g}²⁷ and E_{g}²⁸ are both ≧E_{g}^{m} and <E_{g}^{h} and E_{g}²⁷ is >E_{g}²⁸. The LEGC stack 23 as shown contains two cells 29 and 30 with different energy gaps E_{g}²⁹ and E_{g}³⁰, where E_{g}²⁹ and E_{g}³⁰ are both <E_{g}^{m} and E_{g}²⁹ is >E_{g}³⁰. The dichroic mirror 24 operates at E_{g}^{m} and reflects light with photons of energy≧E_{g}^{m} and transmits light with photons of energy<E_{g}^{h}. Solar light 31 impinges upon the surface of the high energy gap cell 26. High energy gap cell 26 absorbs light with photons of energy≧E_{g}^{h} and transmits light 32 with photons of energy<E_{g}^{h}. The light 32 impinges upon the dichroic mirror 24 which is positioned so that it is not perpendicular to the direction of the light 32. Light 33 with photons of energy≧E_{g}^{m} is reflected by the dichroic mirror and impinges upon the surface of the first cell 27 of the MEGC stack 22. Cells 27 and 28 each absorb light with photons of energy greater than or equal to their energy gap and are transparent to and transmit light with photons of energy less than their energy gap. Light 34 with photons of energy<E_{g}^{m} is transmitted by the dichroic mirror and is reflected by the reflecting mirror 40. The reflected light 34 impinges upon the surface of the first cell 29 of the LEGC stack 23. Cells 29 and 30 each absorb light with photons of energy greater than or equal to their energy gap and are transparent to and transmit light with photons of energy less than their energy gap. The HEGC, MEGC and LEGC stacks are all shown supported by silicon scavenger cells 41A and 41B. A separation 42 between the silicon scavenger cells 41A and 41B is provided to allow for the transmission of light 32. The silicon scavenger cells 41A and 41B absorb light that would otherwise not have been captured.

When a dichroic mirror is used that operates at E_{g}^{m} and reflects light with photons of energy<E_{g}^{m} and transmits light with photons of energy≧E_{g}^{m}, the light 34 shown in FIGS. 2-5 and 7 with photons of energy<E_{g}^{m} is reflected by the dichroic mirror and light 33 with photons of energy≧E_{g}^{m} is transmitted by the dichroic mirror. As a result a MEGC 22 is positioned where the LEGC stack 23 is shown in FIGS. 2-5 and 7 and a LEGC stack 23 is positioned where MEGC stack 22 is shown in FIGS. 2-5 and 7.

Preferably, E_{g}^{m} is about equal to the energy gap of the cell with the lowest energy gap of all the cells to which the component of light with photons of energy≧E_{g}^{m} is directed. When there is a MEGC stack present, as in the “HEGC stack-dichroic mirror-MEGC stack” or “HEGC stack-dichroic mirror-MEGC stack-LEGC stack” architectures, preferably E_{g}^{m} is about equal to the energy gap of the cell with the lowest energy gap of the cells in the MEGC stack. If the component of light with photons of energy≧E_{g}^{m} is further spectrally divided, E_{g}^{m} is about equal to the energy gap of the cell with the lowest energy gap of the cells impinged by the spatially divided light.

Materials suitable for cells for the HEGC stack with energy gaps≧2.0 eV can be selected from the III-V GaInP/AlGaInP and AlInGaN material systems. An InGaN cell with an energy gap of 2.4 eV is a preferred cell material. For preparation see, for example, O. Jani et al., Conference Record, 2006 IEEE 4^{th} World Conference on Photovoltaic Energy Conversion, May 10, 2006, Waikoloa, Hi. When the HEGC stack contains only one cell, InGaN on a sapphire substrate is preferred. The InGaN-sapphire combination has a low index of refraction and reduces the requirements on the optical anti-reflection coatings used to minimize the reflection of solar light from the cell surface. The sapphire substrate could be shaped to serve as a lens

Materials suitable for cells for the MEGC stack with energy gaps<2.0 eV and ≧E_{g}^{m} where E_{g}^{m} is about 1.4 eV can be selected from the III-V GaInP/GaAsP/GaInAs material system. A GaInP cell with an energy gap of 1.84 eV and a GaAs cell with an energy gap of 1.43 eV are two of the preferred cells for the MGEC stack. A two cell MEGC stack consisting of GaInP/IGaAs tandem cells can be prepared using, trimethyl gallium, trimethyl indium, phosphine, arsine and other precursors as described by K. A. Bertness et al., Appl. Phys. Letter 65, 989 (1994).

GaAs is a preferred cell for the cell with the lowest energy gap in a MEGC stack. It is also a preferred cell to be used as the cell with the lowest energy gap when the component of light with photons of energy≧E_{g}^{m} is further spectrally divided. Therefore, it is preferred for E_{g}^{m} to be about 1.43 eV

Cells with energy gaps<E_{g}^{m}, where E_{g}^{m} is about 1.4 eV, suitable for use in the LEGC stack are silicon cells with an energy gap of 1.12 eV and InGaAs cells with energy gaps<1 eV Silicon cells and their preparation are well-known. The InGaAs cells are state of the art devices designed for thermophotovoltaic applications. For preparation see, for example, R. J. Wehrer et al., Conference Record, IEEE Photovoltaic Specialists Conference, 2002, pages 884-887.

In one embodiment, the cells in one or more stacks can be electrically connected in series to provide a single output for the stack. The silicon cells can also be electrically connected in series or in parallel to provide a single output. In a more preferred embodiment, all the individual cells in the HEGC, MEGC and LEGC stacks are contacted with individual electrical connections. This results in a substantial simplification of the solar cell and provides the opportunity to regulate the voltage across each cell at a value to provide optimum operation of the cell. The cells can be connected to a power combiner that provides a single electrical output for the solar cell at the desired voltage. The silicon cells can be connected to the same power combiner. The silicon cells surrounding the active region of the solar cell can also be contacted with electrical connections separate from those of the other cells and from one another.

Light reflected from the surfaces of cells is a potential source of decreased solar cell efficiency. An anti-reflection coating can be applied to the surfaces of any of the cells upon which light impinges to minimize this loss.

In a preferred embodiment, the improved high efficiency solar cell further comprises an optical element. The intensity or concentration of solar raciation striking a surface is 1×, the normal concentration. It is more difficult and more expensive to achieve high solar cell efficiency with 1× solar light than it is using solar light of higher concentrations. The purpose of the optical element is to collect and concentrate the light impinging upon it and direct the light upon the surface of the first cell in the HEGC stack. The optical element comprises a total internal reflecting concentrator that is a static concentrator. This static concentrator increases the power density of the solar light that can be utilized by the solar cell. It is a wide acceptance-angle concentrator that accepts light from a large portion of the sky. Unlike a tracking concentrator, the static concentrator is able to capture most of the diffuse light, much of which is in the blue to ultraviolet portion of the spectrum. This diffuse light makes up about 10% of the incident power in the solar spectrum. In practice, high levels of concentration are achieved by rejecting light from those portions of the sky in which the power density of the solar radiation is low throughout the year. In this way, concentrations of the solar light are increased by a factor of 10×. Higher concentrations are obtained if the position of the concentrator can be adjusted at some time during the year. Light is transmitted through one surface of the concentrator and that surface is adjacent to the surface of the first cell in the HEGC stack. “Solar light” is used herein to refer to the complete solar spectrum that impinges upon the surface of the first cell in the HEGC stack, no matter what the concentration. Preferably, the concentration is 10× or higher.

Preferably, in another aspect of the invention, the improved high efficiency solar cell has a solar module comprising a III-V cell and a silicon cell with an area larger than that of the III-V cell. The silicon cell is a scavenger cell. This solar cell further comprises means to focus light from the sun's disc onto the III-V cell. Recent research on solar cells to increase efficiency has involved the focusing of sunlight from the sun's disc onto high efficiency III-V cells. Focusing the light from the sun's disc onto the III-V cell results in an increase in efficiency of the cell. It also allows the reduction of the required area of the III-V material in the cell. This is important since the III-V cells are generally more expensive than silicon cells. However, only light from the sun's disc is being utilized by the III-V cell. On a clear day only about 85% of the light impinging on the solar cell is from the sun's disc. The scattered light, the other 15% of the solar light, is not focused onto the III-V cell and is wasted. On overcast days when the total solar flux is still about 20% of that on a clear day, nearly all the light is scattered and very little light would reach the III-V cell. There is a need to capture this atmospherically scattered light to improve solar cell efficiency and that is the role played by the silicon scavenger cell.

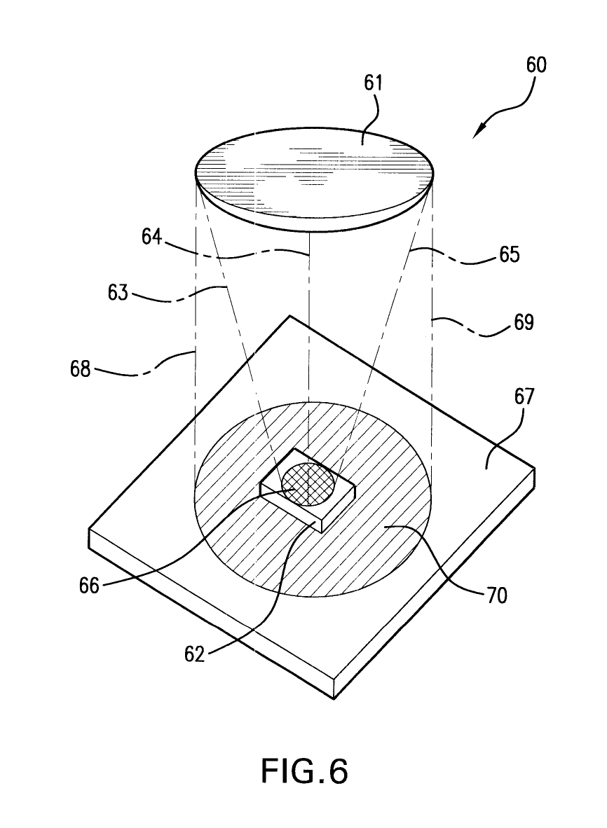

FIG. 6 illustrates an embodiment of the improved solar cell 60 comprising a solar module of the invention and means to focus light from the sun's disc onto the III-V cell. The means to focus the light is represented by lens 61. Lens 61 is positioned so that light from the sun's disc impinges upon the upper surface of the III-V cell 62. The solar cell would be subjected to angular tracking to insure that the light from the sun's disc would continue to be focused on the III-V cell as the position of the sun changes. Lines 63, 64, and 65 represent light rays from the sun's disc that pass through the outer perimeter of lens 61. The cross-hatched area 66 represents the area on the upper surface of the III-V cell that is impinged upon by light from the solar disc and the rays 63, 64 and 65 fall on the perimeter of area 66. The silicon cell 67 is positioned contiguous to the III-V cell's lower surface, i.e., the surface of the III-V cell opposite the surface upon which the solar light impinges. The area of the silicon cell is greater than that of the III-V cell and should be made sufficiently large to capture the major portion of atmospherically scattered light. Lines 68 and 69 represent light rays of the scattered light that pass through the outer perimeter of the lens 61. The diagonally shaded area 70 represents the area on the surface of the silicon cell that is impinged upon by the scattered light and the rays 68 and 69 fall onto the perimeter of the area 70. Light that impinges upon the III-V cell and is not absorbed passes through the III-V cell and is captured by the portion of the silicon cell beneath the III-V cell, thereby providing additional increase in the solar cell efficiency.

The area of the silicon cell required to capture the major portion of the scattered light can be determined for the particular solar cell and the means used to focus the solar light. Typically, the area of the silicon cell is at least about 10 times that of the III-V cell. The silicon cell is adjacent to the side of the III-V cell opposite the side upon which the solar light impinges as described above. Preferably, the silicon cell and the III-V cell are contiguous. Instead of a single silicon cell, multiple silicon cells can be used with their combined area typically at least 10 times that of the III-V cell.

Any of the III-V materials mentioned above can be used for the III-V cell. Preferably, the III-V cell has an energy gap greater than 1.2 eV, and more preferably greater than 1.4 eV. Preferably, the III-V cell is a GaAs-based cell. Preferably, the individual cells are contacted with individual electrical connections.

### EXAMPLE OF A PREFERRED EMBODIMENT

A solar module comprising a III-V cell and a silicon cell with an area larger than that of the III-V cell and means to focus the light onto the III-V cell was fabricated as follows. A 1.05 inch (2.67 cm) square circuit board supported a 0.8×0.6 inch (2×1.5 cm) silicon cell. A 4.3×4.3 mm III-V cell was epoxied onto the center of the silicon cell. The III/V cell was a tandem stacked diode, consisting of two p-n junctions connected electrically in series by a tunnel junction. The top junction was InGaP based, having a band gap of 1.75 electron volts. The bottom junction was GaAs based, having a band gap of 1.42 electron volts. Each cell was about 0.4 mm thick. Wire bonds were connected from each cell to pads on the circuit board so that each cell could be individually accessed and their powers summed by an appropriate circuit. Pins were mounted onto the circuit board for connecting output cables. The majority of the area of the silicon cell was active, i.e., all but the electrode area. The active area of the III-V cell was 3×3.5 mm. The III-V was polished and had an anti-reflection coating on its back side, i.e., the side opposite that upon which the solar light impinges, so that light with photons of energy less than the cell's energy gap passed through the II-V cell and impinged upon the silicon cell. This light transmitted by the III-V cell and the scavenged light that impinged directly upon the silicon cell both contribute to the solar-induced photocurrent in the silicon cell. The means to focus light from the sun's disc onto the III-V cell consisted of a glass lens with a 25 mm diameter and a 25 mm focal length. The lens was supported by and epoxied to a blank circuit board with a hole cut into it that mated with the lens. The lens was supported by ⅞ inch (2.2 cm) metal standoffs. The top of the III-V cell was about 21.4 mm below the center of the lens, i.e., positioned above the focal point of the lens. The solar optical spot on the surface of the III-V cell had a diameter of about 2 mm. An angular variation of the solar light by about 7 degrees would still result in the optical spot falling on the active area of the III-V cell.

In full sun on a clear day, the maximum power output of the III-V cell was 78 milliwatts (37.5 milliamperes at a voltage of 2.05 volts) and the maximum power output of the silicon cell was 10.6 milliwatts (29.9 milliamperes at a voltage of 0.356 volts.

What is claimed is:

1. An improved high efficiency solar cell, the improvement comprising one or more silicon cells surrounding at least a portion of the active region of the solar cell.

2. The improved high efficiency solar cell of claim 1, wherein the silicon cells completely surround the active region of the solar cell.

3. The improved high efficiency solar cell of claim 1, wherein the solar cell architecture is selected from the group consisting of a “high energy gap cell (HEGC) stack-dichroic mirror” architecture, a “HEGC stack-dichroic mirror-mid energy gap cell (MEGC) stack” architecture, a “HEGC stack-dichroic mirror-low energy gap cell (LEGC) stack” architecture and a “HEGC stack-dichroic mirror-MEGC stack-LEGC stack” architecture.

4. The improved high efficiency solar cell of claim 3, wherein the solar cell has the “HEGC stack-dichroic mirror” architecture.

5. The improved high efficiency solar cell of claim 3, wherein the solar cell has the “HEGC stack-dichroic mirror-MEGC stack-LEGC stack” architecture.

6. The improved high efficiency solar cell of claim 4, wherein the dichroic mirror provides a separation of the light transmitted by the HEGC stack into two spectral components, one component of light with photons of energy≧E_{g}^{m} and one component of light with photons of energy<E_{g}^{m} and wherein one of these components is reflected by the dichroic mirror and one is transmitted by the dichroic mirror and wherein E_{g}^{m} is about equal to the energy gap of the cell with the lowest energy gap of all the cells to which the component of light with photons of energy≧E_{g}^{m} is directed.

7. The improved high efficiency solar cell of claim 5, wherein the dichroic mirror provides a separation of the light transmitted by the HEEGC stack into two spectral components, one component of light with photons of energy≧E_{g}^{m} and one component of light with photons of energy<E_{g}^{m} and wherein one of these components is reflected by the dichroic mirror and one is transmitted by the dichroic mirror and wherein E_{g}^{m} is about equal to the energy gap of the cell with the lowest energy gap of cells in the MEGC stack.

8. The high efficiency solar cell of claim 7, wherein the cell with the lowest energy gap is a GaAs cell and E_{g}^{m} is about 1.43 eV

9. The improved high efficiency solar cell of claim 2, wherein the solar cell architecture is selected from the group consisting of a “HEGC stack-dichroic mirror” architecture, a “HEGC stack-dichroic mirror-MEGC stack” architecture, a “HEGC stack-dichroic mirror-LEGC stack” architecture and a “HEGC stack-dichroic mirror-MEGC stack-LEGC stack” architecture.

10. The improved high efficiency solar cell of claim 9, wherein all the individual cells in the HEGC, MEGC and LEGC stacks and the silicon cells surrounding the active region are contacted with individual electrical connections.

11. The improved high efficiency solar cell of claim 1, wherein the solar cell comprises a III-V cell and means to focus light from the sun's disc onto the III-V cell and wherein a silicon cell with an area larger than that of the III-V cell is positioned adjacent to the side of the III-V cell opposite the side upon which the light from the sun's disc impinges.

12. The improved high efficiency solar cell of claim 11, wherein the III-V cell and the silicon cell are contiguous.

13. The improved high efficiency solar cell of claim 11, wherein the area of the silicon cell is at least 10 times that of the III-V cell.

14. An improved high efficiency solar cell comprised of a III-V cell and means to focus light from the sun's disc onto the III-V cell, the improvement comprising a silicon cell with an area larger than that of the III-V cell, wherein the silicon cell is positioned adjacent to the side of the III-V cell opposite the side upon which the light from the sun's disc impinges.

15. The improved high efficiency solar cell of claim 14, wherein the III-V cell and the silicon cell are contiguous.

16. The improved high efficiency solar cell of claim 14, wherein the area of the silicon cell is at least 10 times that of the III-V cell.

17. A solar cell module comprising a III-V cell upon which light from the sun's disc impinges and a silicon cell with an area larger than that of the III-V cell, wherein the silicon cell is positioned adjacent to the side of the III-V cell opposite the side upon which the light from the sun's disc impinges.

18. The solar cell module of claim 17, wherein the III-V cell and the silicon cell are contiguous.

19. The solar cell module of claim 17, wherein the area of the silicon cell is at least 10 times that of the III-V cell.

20. The solar cell module of claim 17, wherein the III-V cell is a tandem stack with a InGaP first cell and a GaAs second cell.
